(19) United States
(12) Patent Application Publication
(10) Pub. No.: US 2013/0308247 A1
(43) Pub. Date: Nov. 21, 2013

(54) METHOD AND APPARATUS FOR TESTING CIRCUIT BOARD

(71) Applicant: HON HAI PRECISION INDUSTRY CO., LTD., New Taipei (TW)

(72) Inventors: TING-YANG LIN, New Taipei (TW); I-CHAN HU, New Taipei (TW); CHENG-TA HU, New Taipei (TW)

(73) Assignee: HON HAI PRECISION INDUSTRY CO., LTD., New Taipei (TW)

(21) Appl. No.: 13/795,548

(22) Filed: Mar. 12, 2013

(30) Foreign Application Priority Data
May 18, 2012 (TW) 101117921

(51) Int. Cl. H03M 11/22

(52) U.S. Cl. CPC H03M 11/22
USPC 361/437

(57) ABSTRACT

An exemplary apparatus for measuring characteristics of a circuit board includes an embedded controller, a first resistor, and a second resistor. The embedded controller includes an A/D (analog to digital) conversion terminal. The A/D conversion terminal receives a DC (direct current) voltage via the first resistor. The A/D conversion terminal is grounded via the second resistor. Resistances of the first resistor and the second resistor indicate different characteristics of the circuit board. The A/D conversion terminal detects a voltage value of a connection point between the first resistor and the second resistor. The embedded controller analyzes characteristics of the circuit board according to the voltage value.

### BACKGROUND

1. Technical Field

The present disclosure relates to a method and an apparatus for measuring characteristics of a circuit board.

2. Description of Related Art

In developing computer systems, such as personal computer systems, an embedded controller is used to measure characteristics of various components on motherboards. Measuring methods include using a plurality of GPIO pins on the embedded controller to detect voltage values of the various components. The characteristics of various components are then analyzed by a CMOS chip on the motherboard. However, such testing methods require a plurality of embedded controllers to complete the test, which is costly.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an embodiment of an apparatus for measuring characteristics of a circuit board.

FIG. 2 is a flow chart of a method for measuring characteristics of a circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

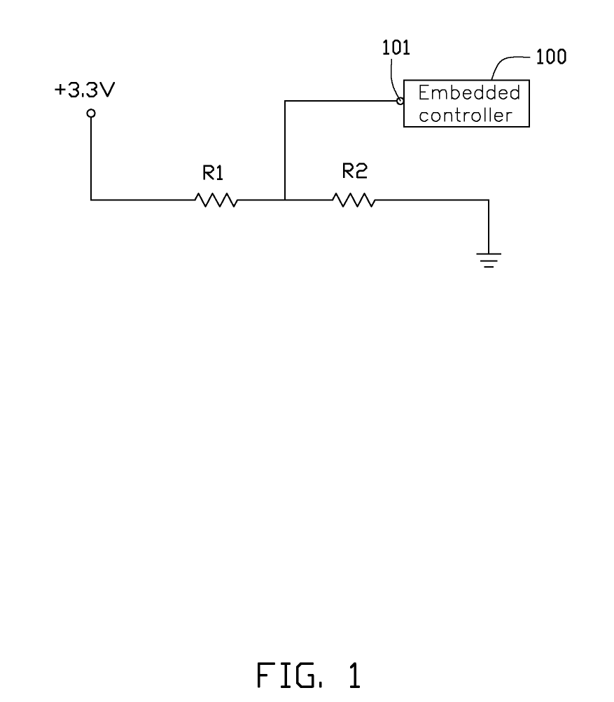

FIG. 1 illustrates a schematic view of an embodiment of an apparatus for measuring characteristics of a motherboard, in accordance with one embodiment. The apparatus includes an embedded controller 100, a first resistor R1, and a second resistor R2.

The embedded controller 100 includes an analog to digital (A/D) conversion terminal 101. The A/D conversion terminal 101 receives a direct current (DC) voltage via the first resistor R1. The A/D conversion terminal 101 is grounded via the second resistor R2. Resistances of the first resistor R1 and the second resistor R2 indicate different characteristics of the motherboard. The A/D conversion terminal 101 detects a DC voltage value between a connection point of the first resistor R1 and the second resistor R2 and ground. Various possible DC voltages respectively correspond to a plurality of reference binary codes. The embedded controller 100 determines a binary code corresponding to characteristics of the motherboard according to the voltage value and the reference binary code. The embedded controller 100 determines characteristics of the motherboard according to the binary code. In one embodiment, the DC voltage is +3.3V. The reference binary code is 1111111111. The A/D conversion terminal 101 is a ten bits A/D conversion terminal. The reference binary code is a ten bit binary code. Each bit of the ten bit reference binary code indicates status of a particular characteristic of the motherboard. The characteristics of the motherboard include developing process information (type of the motherboard), video chip information, High Definition Multimedia Interface (HDMI) information, and network chip information. In other embodiments, any of various other kinds of circuit boards can be measured and analyzed instead of the motherboard.

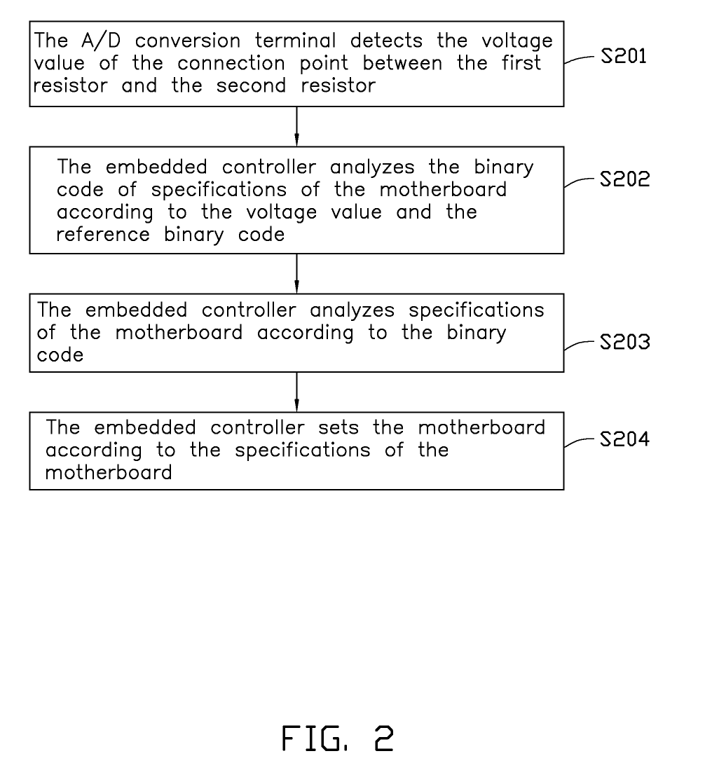

FIG. 2 illustrates a flow chart of an embodiment of a method for measuring characteristics of the motherboard, in accordance with one embodiment. Depending on the embodiment, certain steps described below may be removed, while others may be added, and the sequence of the steps may be altered. In one embodiment, the method for autonomous monitoring utilizing the above-described system includes the following steps:

S201: the A/D conversion terminal 101 measures the voltage value between the connection point of the first resistor R1 and the second resistor R2 and ground;

S202: the embedded controller 100 analyzes the binary code of characteristics of the motherboard according to the voltage value and the reference binary code;

S203: the embedded controller 100 determines characteristics of the motherboard according to the binary code;

S204: the embedded controller 100 sets default values and operating parameters of the motherboard according to the characteristics of the motherboard.

For example, when the A/D conversion terminal 101 detects the voltage value is 2.58V, a decimal code of the reference binary code is 1023. A decimal code of the voltage value 2.58V is calculated with the following formula: 2.58÷3.3×1023=800. A binary code of the decimal code 800 is 1100100000, which indicates the motherboard is a PV type motherboard having a 100 mbps network chip, a HDMI, and a independent video chip.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An apparatus for measuring characteristics of a circuit board comprising:
an embedded controller, a first resistor, and a second resistor; wherein the embedded controller comprises an analog to digital (A/D) conversion terminal; the A/D conversion terminal receives a direct current (DC) voltage via the first resistor; the A/D conversion terminal is grounded via the second resistor; resistances of the first resistor and the second resistor indicate different characteristics of the circuit board; the A/D conversion terminal detects a voltage value of a connection point between the first resistor and the second resistor; and the embedded controller analyzes characteristics of the circuit board according to the voltage value.

2. The apparatus of claim 1, wherein the DC voltage indicates a reference binary code;
and the embedded controller analyzes a binary code of characteristics of the circuit board according to the voltage value and the reference binary code.

3. The apparatus of claim 2, wherein the A/D conversion terminal is a ten bits A/D conversion terminal; the reference binary code is a ten bits binary code; and the embedded controller analyzes characteristics of the circuit board according to the binary code of the circuit board.

4. The apparatus of claim 3, wherein the DC voltage is +3.3V.

5. The apparatus of claim 4, wherein the characteristics of the circuit board comprises developing process information, video chip information, High Definition Multimedia Interface (HDMI) information, and network chip information.

6. A method for measuring characteristics of a circuit board, the method comprising:
measuring a voltage value of a connection point between a first resistor and a second resistor by an analog to digital (A/D) conversion terminal on an embedded controller; wherein embedded controller stores a reference binary code;
analyzing a binary code of characteristics of the circuit board according to the voltage value and the reference binary code by the embedded controller;
analyzing characteristics of the circuit board according to the binary code by the embedded controller; and
setting the circuit board according to the characteristics of the circuit board by the embedded controller.

7. The method of claim 6, wherein the A/D conversion terminal receives a direct current (DC) voltage via the first resistor; and the A/D conversion terminal is grounded via the second resistor.

8. The method of claim 7, wherein resistances of the first resistor and the second resistor indicate different characteristics of the circuit board; and the DC voltage indicates the reference binary code.

9. The method of claim 8, wherein the A/D conversion terminal is a ten bits A/D conversion terminal; and the reference binary code is a ten bits binary code.

10. The method of claim 9, wherein the characteristics of the circuit board comprise developing process information, video chip information, High Definition Multimedia Interface (HDMI) information, and network chip information.
